(19) United States
(12) Patent Application Publication
(10) Pub. No.: US 2025/0275407 A1
(43) Pub. Date: Aug. 28, 2025

(54) DISPLAY APPARATUS HAVING A PAD AREA

(71) Applicant: LG Display Co., Ltd., Seoul (KR)

(72) Inventors: Gyu Bum JANG, Paju-si (KR); Hyun Haeng LEE, Paju-si (KR)

(73) Assignee: LG Display Co., Ltd., Seoul (KR)

(21) Appl. No.: 18/974,329

(22) Filed: Dec. 9, 2024

(30) Foreign Application Priority Data
Feb. 27, 2024 (KR) 10-2024-0028329

(51) Int. Cl. H10K 59/131; H10K 59/121; H10K 59/126

(52) U.S. Cl. CPC H10K 59/1315; H10K 59/1213; H10K 59/126

(57) ABSTRACT

A display apparatus can include an active area in which pixel areas are disposed and a bezel area disposed outside the active area. The pad area can be disposed in the bezel area. The pad area can include a plurality of voltage pads disposed side by side along an edge of the active area. A power voltage supply line surrounding the active area can be electrically connected to the plurality of voltage pads. A resistance of each voltage pad can decrease toward the center of the pad area. Thus, in the display apparatus, a heat generation due to a difference in current paths between the power voltage supply line and each voltage pad can be prevented or minimized.

### CROSS-REFERENCE TO RELATED APPLICATIONS

This application claims priority to Korean Patent Application No. 10-2024-0028329, filed in the Republic of Korea on Feb. 27, 2024, the entire disclosure of which is hereby expressly incorporated by reference into the present application.

### BACKGROUND

### Field

The present disclosure relates to a display apparatus having a pad area.

### Discussion of the Related Art

Generally, a display apparatus provides an image to a user. For example, the display apparatus can include pixel areas on a device substrate. Each of the pixel areas can realize a specific color. For example, a driving circuit electrically connected to a light-emitting device can be disposed in each pixel area.

Various signals can be applied to each pixel area through signal wirings. For example, the signal wirings can include gate lines applying a gate signal, data lines applying a data signal, and power voltage supply lines supplying a power voltage. A power unit electrically connected to the power voltage supply lines can be disposed outside the device substrate. For example, the device substrate can include an active area in which the pixel areas are disposed and a bezel area disposed outside the active area, and a pad area including voltage pads electrically connected to the power unit can be disposed within the bezel area.

Each of the power voltage supply lines can be electrically connected to a plurality of voltage pads for stable connection. However, in the display apparatus, the voltage pads electrically connected to each power voltage supply line can have different current paths. Thus, in the display apparatus, a current can be concentrated on one of the voltage pads that has a relatively short current path. That is, in the display apparatus, heat can be generated due to a difference in the current paths. As such, in the display apparatus, the light-emitting devices disposed close to the pad area can be deteriorated due to the heat generated in one of the voltage pads.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of reducing the damage of the light-emitting devices due to heat.

Another object of the present disclosure is to provide a display apparatus capable of preventing or minimizing the generation of heat due to a difference in the current path.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. The device substrate includes an active area and a bezel area. The bezel area is disposed outside the active area. A pad area is disposed in the bezel area. The pad area includes a first voltage pad and a second voltage pad. The first voltage pad and the second voltage pad are disposed side by side along an edge of the active area. The first voltage pad and the second voltage pad are electrically connected to a power voltage supply line. The power voltage supply line extends along an edge of the device substrate. The first voltage pad is disposed between the second voltage pad and a side of the device substrate. The second voltage pad has a different resistance from a first voltage pad.

According to aspects of the present disclosure, a distance between the power voltage supply line and the side of the device substrate in the outside of the pad area can be smaller than a distance between the first voltage pad and the side of the device substrate in the outside of the pad area.

According to aspects of the present disclosure, the second voltage pad can have a stacked structure same as the first voltage pad.

According to aspects of the present disclosure, each of the first voltage pad and the second voltage pad can include a first pad electrode and a second pad electrode. The second pad electrode can be disposed on the first pad electrode. The first pad electrode can include a same material as the power voltage supply line.

According to aspects of the present disclosure, a horizontal width of the second voltage pad can be different from a horizontal width of the first voltage pad.

According to aspects of the present disclosure, the second voltage pad can have a same length as the first voltage pad.

According to aspects of the present disclosure, the pad area can include a third voltage pad. The third voltage pad can be electrically connected to the power voltage supply line. The second voltage pad can be disposed between the first voltage pad and the third voltage pad. The second voltage pad can have a resistance between the first voltage pad and the third voltage pad. A horizontal width of the second voltage pad can be between a horizontal width of the first voltage pad and a horizontal width of the third voltage pad.

According to aspects of the present disclosure, a distance between the second voltage pad and the third voltage pad can be different from a distance between the first voltage pad and the second voltage pad.

According to aspects of the present disclosure, a signal applied to the power voltage supply line through the second voltage pad can be the same as a signal applied to the power voltage supply line through the first voltage pad.

According to aspects of the present disclosure, the signal applied to power voltage supply line through the first voltage pad and the second voltage pad can be a negative power voltage.

According to aspects of the present disclosure, the pad area can include a third voltage pad, a fourth voltage pad, a fifth voltage pad, and a sixth voltage pad successively disposed side by side along the edge of the active area and next to the second voltage pad. The sixth voltage pad can be connected to the first voltage pad. The fifth voltage pad can be connected to the second voltage pad. The fourth voltage pad can be connected to the third voltage pad.

In another embodiment of the present disclosure, there is provided a display apparatus comprising a device substrate. The device substrate includes an active area and a bezel area. The bezel area is disposed outside the active area. A pad area is disposed in the bezel area. The pad area includes a plurality of voltage pads disposed side by side. The plurality of voltage pads is electrically connected to a power voltage supply line. The power voltage supply line extends along an edge of the device substrate. An area of a region for the connection between each voltage pad and the power voltage supply line increases toward the center of the pad area.

According to aspects of the present disclosure, a plane of each voltage pad can have a same shape as a plane of adjacent voltage pad.

According to aspects of the present disclosure, each of the plurality of voltage pads can include a lower pad electrode and an upper pad electrode. The upper pad electrode can be disposed on the lower pad electrode. The power voltage supply line can be electrically connected to the lower pad electrode of each voltage pad through at least one pad contact hole. The number of the pad contact hole connecting between the lower pad electrode of each voltage pad and the power voltage supply line can increase toward the center of the pad area.

According to aspects of the present disclosure, each of the plurality of voltage pads can include a first end and a second end. The first end of each voltage pad can be toward the power voltage supply line. The second end of each voltage pad can be opposite to the first end of the corresponding voltage pad. The pad contact hole connecting between the lower pad electrode of each voltage pad and the power voltage supply line can be disposed close to the second end of the corresponding voltage pad.

According to aspects of the present disclosure, connection electrodes can be disposed between the power voltage supply line and each voltage pad. Each of the plurality of voltage pads can be electrically connected to the power voltage supply line through one of the connection electrodes.

According to aspects of the present disclosure, the connection electrodes can be disposed on a different layer than the power voltage supply line.

According to aspects of the present disclosure, a driving circuit, a light-emitting device and a light-blocking pattern can be disposed on a pixel area of the active area. The driving circuit can include at least one thin film transistor. The light-emitting device can be electrically connected to the driving circuit. The light-blocking pattern can be disposed between the device substrate and a semiconductor pattern of the thin film transistor. The connection electrodes can be disposed on a same layer as the light-blocking pattern.

According to aspects of the present disclosure, each of the plurality of voltage pads can include a lower pad electrode and an upper pad electrode disposed on the lower pad electrode. An area of the lower pad electrode of each voltage pad can decrease toward an edge of the pad area.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to some embodiments of the present disclosure;

FIG. 2 is a view showing a circuit of a pixel area in the display apparatus according to the embodiments of the present disclosure;

FIG. 3 is a view showing a cross-section of a pixel area in the display apparatus according to the embodiments of the present disclosure;

FIG. 4 is an enlarged view of K1 region in FIG. 1;

FIG. 5 is an enlarged view of K2 region in FIG. 4;

FIG. 6 is a view taken along line I-I′ of FIG. 5; and

FIGS. 7 to 11 are views showing the display apparatus according to another embodiment of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the disclosure and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element and may not define order or sequence. However, the first element and the second element can be arbitrary named according to the convenience of those skilled in the art without departing the technical sprit of the present disclosure.

The terms used in the disclosure of the present disclosure are merely used in order to describe particular embodiments, and are not intended to limit the scope of the present disclosure. For example, an element described in the singular form is intended to include a plurality of elements unless the context clearly indicates otherwise. In addition, in the disclosure of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

Further, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship. Further, the term “can” encompasses all the meanings and coverages of the term “may.”

All the components of each display device or apparatus according to all embodiments of the present disclosure are operatively coupled and configured.

### EMBODIMENTS

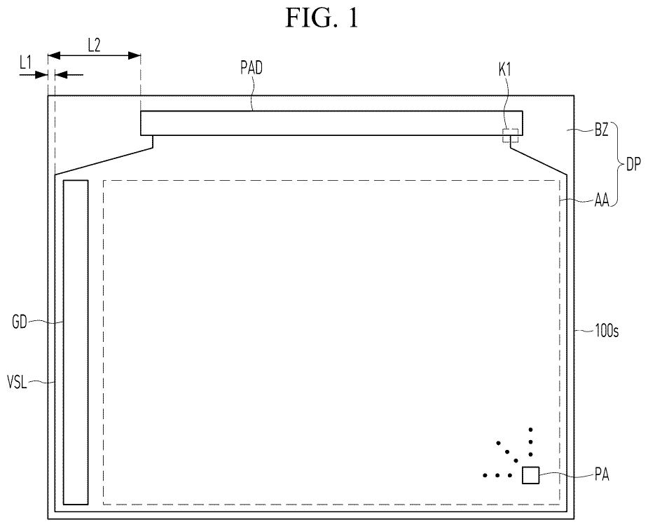

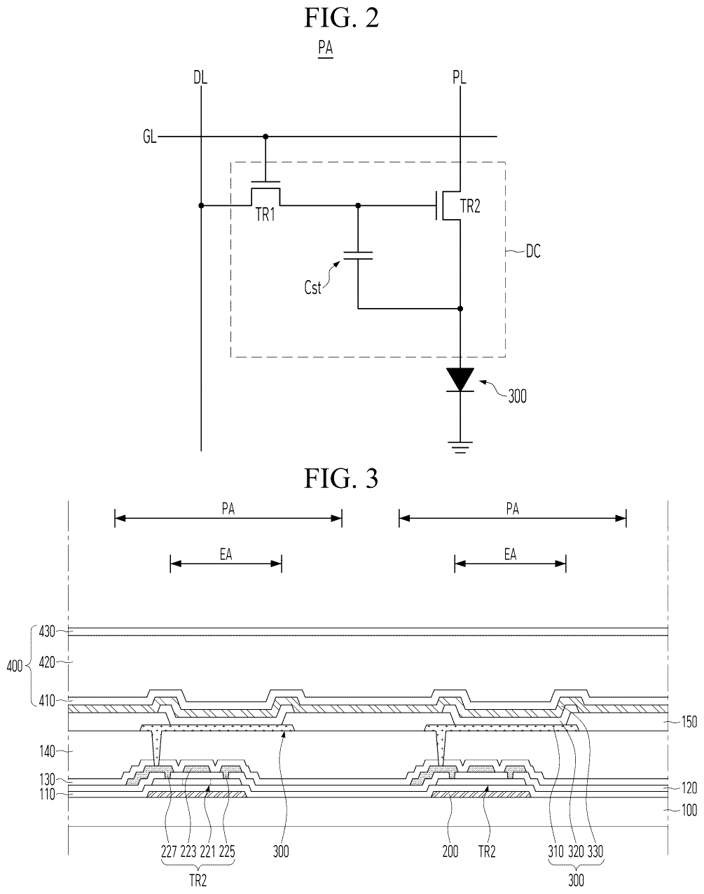

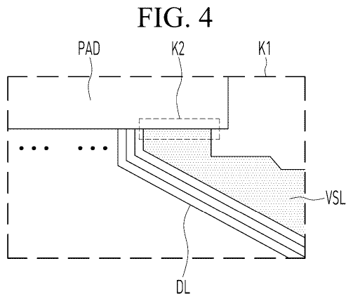

FIG. 1 is a view schematically showing a display apparatus according to some embodiments of the present disclosure. FIG. 2 is a view showing a circuit of a pixel area in the display apparatus according to the embodiments of the present disclosure. FIG. 3 is a view showing a cross-section of a pixel area in the display apparatus according to the embodiments of the present disclosure.

Referring to FIGS. 1 to 3, the display apparatus according to the embodiments of the present disclosure can include a display panel DP. The display panel DP can generate an image provided to a user. For example, pixel areas PA can be disposed in the display panel DP. Various signals can be applied in each pixel area PA through signal wirings GL, DL and PL. For example, the signal wirings GL, DL and PL can include gate lines GL for applying a gate signal, data lines DL for applying a data signal, and first power voltage supply lines PL for supplying a first power voltage.

Each of the pixel areas PA can emit light displaying a specific color according to signals applied through the signal wirings GL, DL and PL. For example, a driving circuit DC electrically connected to a light-emitting device 300 can be disposed in each pixel area PA. The driving circuit DC of each pixel area PA can control the light-emitting device 300 of the corresponding pixel area PA by a signal applied through the signal wirings GL, DL and PL. For example, the driving circuit DC of each pixel area PA can supply a driving current corresponding to the data signal to the light-emitting device 300 of the corresponding pixel area PA according to the gate signal. The driving current supplied by the driving circuit DC of each pixel area PA can maintain for one frame. For example, the driving circuit DC of each pixel area PA can include a first thin film transistor TR1, a second thin film transistor TR2 and a storage capacitor Cst.

The first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern, a first gate electrode, a first drain electrode and a first source electrode. The first semiconductor pattern can include a semiconductor material. The first semiconductor pattern can include a first drain region, a first channel region and a first source region. The first gate electrode can overlap the first channel region of the first semiconductor pattern. The first drain electrode and the first source electrode can be insulated from the first gate electrode. The first drain electrode can be electrically connected to the first drain region of the first semiconductor pattern. The first source electrode can be electrically connected to the first source region of the first semiconductor pattern. For example, the first gate electrode of each pixel area PA can be electrically connected to the corresponding gate line GL, and the first drain electrode of each pixel area PA can be electrically connected to the corresponding data line DL.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can include a second semiconductor pattern 221, a second gate electrode 223, a second drain electrode 225 and a second source electrode 227. For example, the second gate electrode 223 of each pixel area PA can be electrically connected to the first source electrode of the corresponding pixel area PA, and the second drain electrode 225 of each pixel area PA can be electrically connected to the first power voltage supply line PL.

The second semiconductor pattern 221 can include a semiconductor material. For example, the second semiconductor pattern 221 can include low-temperature poly-Si (LPTS) or an oxide semiconductor, such as IGZO. The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second semiconductor pattern 221 can include a second drain region, a second channel region and a second source region. The second channel region can be disposed between the second drain region and the second source region. The second drain region and the second source region can have a resistance smaller than the second channel region. For example, the second drain region and the second source region can include a conductive region of an oxide semiconductor. The second channel region can be a region of an oxide semiconductor, which is not conductorized.

The second gate electrode 223 can be disposed on a portion of the second semiconductor pattern. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a same material as the second gate electrode 223. The second drain electrode 225 can be disposed on a same layer as the second gate electrode 223. The second drain electrode 225 can be formed by a same process as the second gate electrode 223. For example, the second drain electrode 225 can be formed simultaneously with the second gate electrode 223. The second drain electrode 225 can be electrically connected to the second drain region of the second semiconductor pattern 221. The second drain electrode 225 can be spaced apart from the second gate electrode 223.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a same material as the second gate electrode 223. The second source electrode 227 can be disposed on a same layer as the second gate electrode 223. The second source electrode 227 can be formed by a same process as the second gate electrode 223. For example, the second source electrode 227 can be formed simultaneously with the second gate electrode 223. The second source electrode 227 can be electrically connected to the second source region of the second semiconductor pattern 221. The second source electrode 227 can be spaced apart from the second gate electrode 223 and the second drain electrode 225.

The storage capacitor Cst of each pixel area PA can maintain a voltage applied to the second gate electrode 223 of the corresponding pixel area PA for one frame. For example, the storage capacitor Cst of each pixel area PA can be electrically connected to the second gate electrode 223 and the second source electrode 227 of the corresponding pixel area PA. The storage capacitor Cst of each pixel area PA can have a stacked structure of capacitor electrodes. For example, the storage capacitor Cst of each pixel area PA include a first capacitor electrode electrically connected to the second gate electrode 223 of the corresponding pixel area PA and a second capacitor electrode electrically connected to the second source electrode 227 of the corresponding pixel area PA. The first capacitor electrode or the second capacitor electrode of each pixel area PA can be formed by using a process of forming the first thin film transistor TR1 and the second thin film transistor TR2 of the corresponding pixel area PA. For example, the first capacitor electrode of each pixel area PA can be disposed on a same layer as the second gate electrode 223 of the corresponding pixel area PA. The first capacitor electrode of each pixel area PA can be formed by a same process as the second gate electrode 223 of the corresponding pixel area PA. For example, the first capacitor electrode of each pixel area PA can be formed simultaneously with the second gate electrode 223 of the corresponding pixel area PA. Thus, in the display apparatus according to the embodiment of the present disclosure, a process of forming the driving circuit DC in each pixel area PA can be simplified.

The light-emitting device 300 and the driving circuit DC of each pixel area PA can be supported by a device substrate 100. For example, the light-emitting device 300 and the driving circuit DC of each pixel area PA can be disposed on the device substrate 100. The device substrate 100 can include an insulating material. For example, the device substrate 100 can include glass or plastic.

A plurality of insulating layers 110, 120, 130, 140 and 150 for preventing unnecessary electrical connection can be disposed on the device substrate 100. For example, a buffer insulating layer 110, a gate insulating layer 120, a device passivation layer 130, a planarization layer 140 and a bank insulating layer 150 can be disposed on the device substrate 100.

The buffer insulating layer 110 can be disposed on the device substrate 100. The buffer insulating layer 110 can prevent the pollution due to the device substrate 100 in a process of forming the driving circuit DC of each pixel area PA. For example, the buffer insulating layer 110 can extend along an upper surface of the device substrate 100 toward the driving circuit DC of each pixel area PA. The driving circuit DC of each pixel area PA can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

Light-blocking patterns 200 can be disposed between a device substrate 100 and the buffer insulating layer 110 of each pixel area PA. The light-blocking patterns 200 can include a material reflecting or absorbing light. For example, the light-blocking patterns 200 can include a metal. The light-blocking patterns 200 of each pixel area PA can overlap the first semiconductor pattern and the second semiconductor pattern 221 of the corresponding pixel area PA. Thus, in the display apparatus according to the embodiment of the present disclosure, the light travelling toward the first semiconductor pattern and/or the second semiconductor pattern 221 of each pixel area PA passing through the device substrate 100 can be blocked by the light-blocking patterns 200. Thus, in the display apparatus according to the embodiment of the present disclosure, the change in the characteristics of the first thin film transistor TR1 and the second thin film transistor TR2 in each pixel area PA due to an external light can be prevented.

The gate insulating layer 120 can be disposed on the buffer insulating layer 110. The first gate electrode of each pixel area PA can be insulated from the first semiconductor pattern of the corresponding pixel area PA by the gate insulating layer 120. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The device passivation layer 130 can be disposed on the gate insulating layer 120. The device passivation layer 130 can prevent the damage of the driving circuit DC in each pixel area PA due to the external impact and moisture. For example, the first gate electrode, the first drain electrode, the first source electrode, the second gate electrode 223, the second drain electrode 225 and the second source electrode 227 of each pixel area PA can be covered by the device passivation layer 130. The device passivation layer 130 can extend beyond the driving circuit DC of each pixel area PA. The device passivation layer 130 can include an insulating material. For example, the device passivation layer 130 can be a linear insulating layer made of an inorganic insulating material.

The planarization layer 140 can be disposed on the device passivation layer 130. The planarization layer 140 can remove a thickness difference due to the driving circuit DC of each pixel area PA. For example, an upper surface of the planarization layer 140 opposite to the device substrate 100 can be flat. The upper surface of the planarization layer 140 can be parallel to the upper surface of the device substrate 100. The planarization layer 140 can include an insulating material. The planarization layer 140 can include a different material from the device passivation layer 130. The planarization layer 140 can include a material having a relatively high fluidity. For example, the planarization layer 140 can include an organic insulating material.

The light-emitting device 300 of each pixel area PA can be disposed on the planarization layer 140. The light-emitting device 300 of each pixel area PA can emit light displaying a specific color. For example, the light-emitting device 300 of each pixel area PA can include a first electrode 310, a light-emitting layer 320 and a second electrode 330, which are sequentially stacked on the planarization layer 140 of the corresponding pixel area PA.

The first electrode 310 can include a conductive material. The first electrode 310 can include a material having a high reflectance. For example, the first electrode 310 can include a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting layer 320 can generate light having luminance corresponding to a voltage difference between the first electrode 310 and the second electrode 330. For example, the light-emitting layer 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting layer 320 can have a multi-layer structure. For example, the light-emitting layer 320 can include at least one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting layer 320 can be improved.

The second electrode 330 can include a conductive material. The second electrode 330 can include a different material from the first electrode 310. A transmittance of the second electrode 330 can be greater than a transmittance of the first electrode 310. For example, the second electrode 330 can be a transparent electrode made of a transparent conductive material, such as ITO and IZO. Thus, in the display apparatus according to the embodiment of the present disclosure, the light generated by the light-emitting layer 320 can be emitted outside through the second electrode 330. The second electrode 330 can have a work-function smaller than the first electrode 310. For example, the first electrode 310 can function as anode electrode, and the second electrode 330 can function as cathode electrode.

The bank insulating layer 150 can be disposed on the planarization layer 140. The bank insulating layer 150 can define an emission area in each pixel area PA. The first electrode 310 of each pixel area PA can be insulated from the first electrode 310 of adjacent pixel area PA by the bank insulating layer 150. For example, an edge of the first electrode 310 in each pixel area PA can be covered by the bank insulating layer 150. The first electrode 310 of each pixel area PA can be partially exposed by the bank insulating layer 150. The light-emitting layer 320 and the second electrode 330 of each pixel area PA can be stacked on a portion of the corresponding first electrode 310 exposed by the bank insulating layer 150. For example, the light-emitting layer 320 can be in direct contact with the first electrode 310 and the second electrode 330 on the emission area EA defined in each pixel area PA by the bank insulating layer 150. The bank insulating layer 150 can include an insulating material. For example, the bank insulating layer 150 can include an organic insulating material. The bank insulating layer 150 can include a different material from the planarization layer 140.

The first electrode 310 of each pixel area PA can be electrically connected to the driving circuit DC of the corresponding pixel area PA. For example, the first electrode 310 of each pixel area PA can be in direct contact with the second source electrode 227 of the corresponding pixel area PA by penetrating the planarization layer 140. The planarization layer 140 can include pixel contact holes partially exposing the second source electrode 227 of each pixel area PA. The first electrode 310 of each pixel area PA can be connected to the second source electrode 227 of the corresponding pixel area PA through one of the pixel contact holes. The pixel contact holes can overlap the bank insulating layer 150. Thus, in the display apparatus according to the embodiment of the present disclosure, the change in the location of the first electrode 310 in the emission area EA of each pixel area PA can be minimized. For example, a portion of the first electrode 310 overlapping with the emission area EA of each pixel area PA can be in direct contact with the upper surface of the planarization layer 140. Therefore, in the display apparatus according to the embodiment of the present disclosure, the luminance variation according to the generation location of the light emitted from the emission area EA of each pixel area PA can be prevented.

The light emitted from the light-emitting device 300 of each pixel area PA can display a different color from the light emitted from the light-emitting device 300 of adjacent pixel area PA. For example, the light-emitting layer 320 of each pixel area PA can be spaced apart from the light-emitting layer 320 of adjacent pixel area PA. The light-emitting layer 320 of each pixel area PA can include a different material from the light-emitting layer 320 of adjacent pixel area PA. For example, the light-emitting layer 320 of each pixel area PA can have a stacked structure different from the light-emitting layer 320 of adjacent pixel area PA. The light-emitting layer 320 of each pixel area PA can include an end portion disposed on the bank insulating layer 10.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can extend beyond the corresponding pixel area PA. For example, the second electrode 330 of each pixel area PA can be in direct contact with the second electrode 330 of adjacent pixel area PA. Thus, in the display apparatus according to the embodiment of the present disclosure, a process of forming the second electrode 330 in each pixel area PA can be simplified. Further, in the display apparatus according to the embodiment of the present disclosure, the luminance of the light generated by the light-emitting unit 320 of each pixel area PA can be adjusted by the data signal applied to the driving circuit DC of the corresponding pixel area PA.

An encapsulation structure 400 can be disposed on the light-emitting device 300 of each pixel area PA. The encapsulation structure 400 can prevent the damage of the light-emitting device devices 300 due to the external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, the damage of the light-emitting devices 300 due to the external impact and moisture can be effectively prevented. A thickness difference due to the light-emitting device 300 of each pixel area PA can be removed by the second encapsulating layer 420. The second encapsulating layer 420 can have a greater thickness than the first encapsulating layer 410 and the third encapsulating layer 430. For example, an upper surface of the encapsulation structure 400 opposite to the device substrate 100 can be a flat surface. The upper surface of the encapsulation structure 400 can be parallel to the upper surface of the device substrate 100.

The display panel DP can include an active area AA in which the pixel areas PA are disposed, and a bezel area BZ being disposed outside the active area AA. The bezel area BZ can be disposed outside the pixel areas PA. For example, the active area AA can be surrounded by the bezel area BZ. The gate driver GD electrically connected to the gate lines GL, the data driver electrically connected to the data lines DL and the power unit electrically connected to the first power voltage supply lines PL can be disposed outside the active area AA. For example, each of the signal wirings GL, DL and PL can include a region disposed on the bezel area BZ. At least one of the gate driver GD, the data driver and the power unit can be disposed on the bezel area BZ of the display panel DP. For example, the display apparatus according to the embodiment of the present disclosure can be a GIP (Gate In Panel) type display apparatus in which the gate driver GD is formed on the bezel area BZ.

A pad area PAD in which an external signal is applied can be disposed within the bezel area BZ. The data driver and the power unit which are disposed outside the display panel DP can apply a signal through the pad area PAD. For example, the data lines DL can be electrically connected to the data driver through the pad area PAD, and the first power voltage supply lines PL can be electrically connected to the power unit through the pad area PAD.

A second power voltage supply line VSL can be disposed on the bezel area BZ. The second power voltage supply line VSL can supply a second voltage to the gate driver GD and the active area AA. The second power voltage can be different from the first power voltage. For example, the first power voltage can be a positive power voltage (VDD), and the second power voltage can be a negative power voltage (VSS). The second power voltage supply line VSL can extend along an edge of the device substrate 100. For example, the second electrode 330 of each pixel area PA can be electrically connected to the second power voltage supply line VSL on the bezel area BZ. Sides of the active area AA that are not toward the pad area PAD can be surrounded by the second power voltage supply line VSL. The second power voltage supply line VSL can be disposed close to the side 100s of the device substrate 100 at the outside of the pad area PAD, as shown in FIG. 1. For example, a distance L1 between the side 100s of the device substrate 100 and the second power voltage supply line VSL at the outside of the pad area PAD can be smaller than a distance L2 between the side 100s of the device substrate 100 and the side of the pad area PAD. The gate driver GD can be disposed between the active area AA and the second power voltage supply line VSL. The second power voltage supply line VSL can be electrically connected to the pad area PAD.

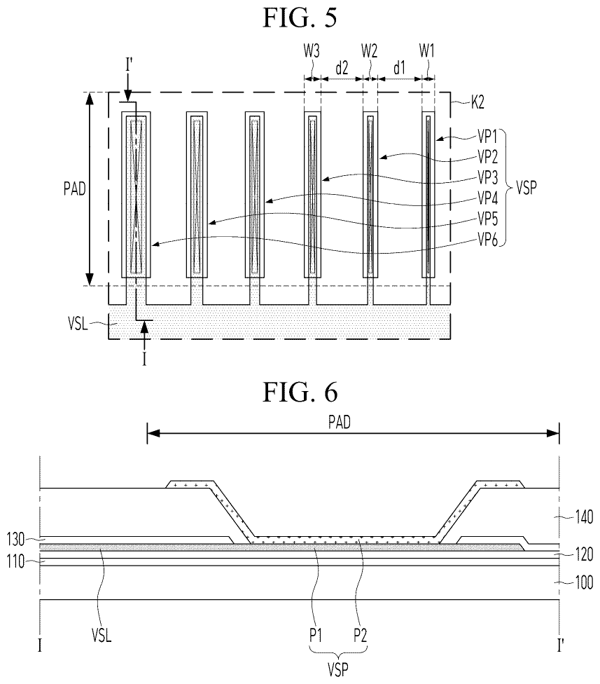

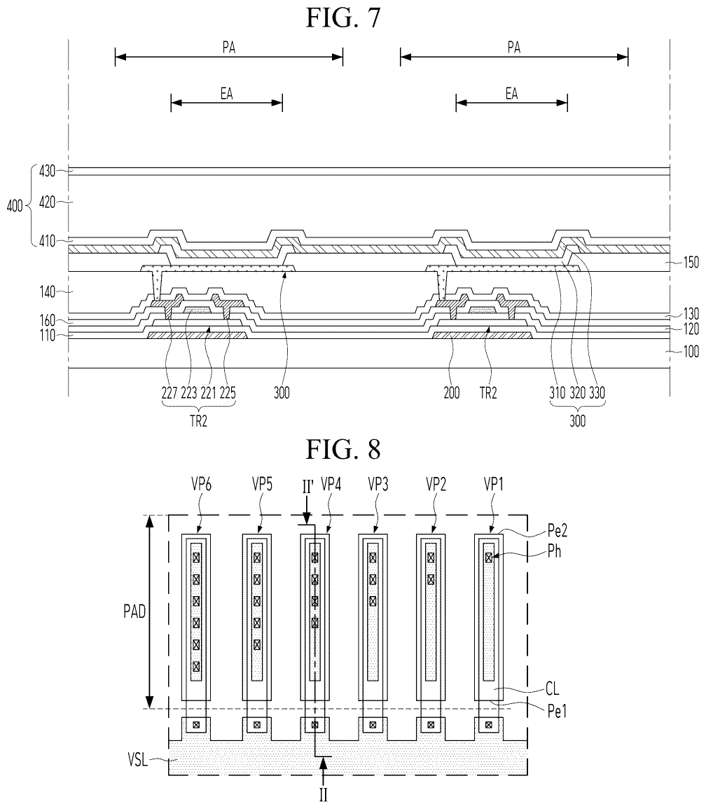

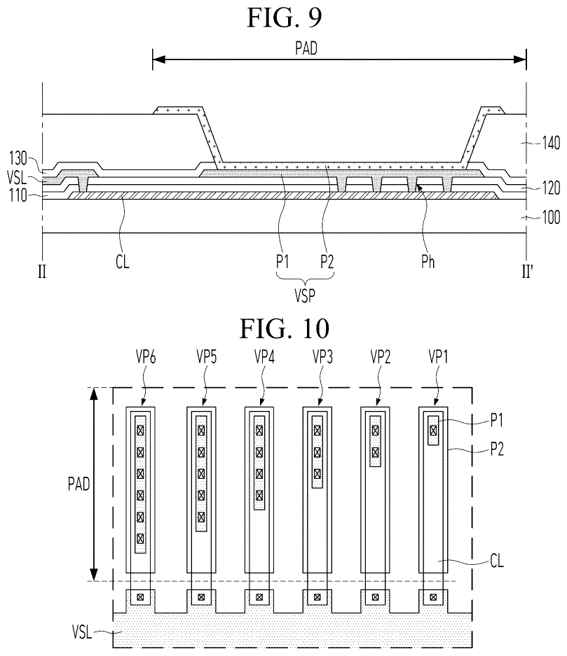

FIG. 4 is an enlarged view of K1 region in FIG. 1. FIG. 5 is an enlarged view of K2 region in FIG. 4. FIG. 6 is a view taken along line I-I′ of FIG. 5.

Referring to FIGS. 1 to 6, the second power voltage supply line VSL can be formed by using a process of forming the driving circuit DC of each pixel area PA. For example, the second power voltage supply line VSL can include a same material as the second gate electrode 223 of each pixel area PA. The second power voltage supply line VSL can be disposed on a same layer as the second gate electrode 223 of each pixel area PA. For example, the second power voltage supply line VSL can be disposed between the gate insulating layer 120 and the device passivation layer 130 of the bezel area BZ. The second power voltage supply line VSL can be formed by a same process as the second gate electrode 223 of each pixel area PA. For example, the second power voltage supply line VSL can be formed simultaneously with the second gate electrode 223 of each pixel area PA.

The pad area PAD can include a plurality of voltage pads VSP electrically connected to the second power voltage supply line VSL. A signal supplied to the second power voltage supply line VSL through each voltage pad VSP can be a same as a signal supplied to the second power voltage supply line VSL through adjacent voltage pad VSP. For example, the negative power voltage can be supplied to the second power voltage supply line VSL through each voltage pas VSP. The plurality of voltage pads VSP can be disposed at an edge of the pad area PAD. For example, the second power voltage supply line VSL can be electrically connected to the pad area PAD at the outside of the data lines DL. The plurality of voltage pads VSP can be disposed side by side. For example, the plurality of voltage pads VSP can include a first voltage pad VP1, a second voltage pad VP2, a third voltage pad VP3, a fourth voltage pad VP4, a fifth voltage pad VP5 and a sixth voltage pad VP6, which are disposed side by side along an edge of the active area AA. The second power voltage supply line VSL can be electrically connected to the first voltage pad VP1, a second voltage pad VP2, a third voltage pad VP3, a fourth voltage pad VP4, a fifth voltage pad VP5 and a sixth voltage pad VP6. Thus, in the display apparatus according to the embodiment of the present disclosure, the second power voltage supply line VSL can be stably connected to the power unit.

The first voltage pad VP1 can be disposed close to an edge of the pad area PAD. The sixth voltage pad VP6 can be disposed close to a center of the pad area PAD. For example, the first voltage pad VP1 can be disposed between the second voltage pad VP2 and a side of the device substrate 100, the third voltage pad VP3 can be disposed between the second voltage pad VP2 and the fourth voltage pad VP4, and the fifth voltage pad VP5 can be disposed between the fourth voltage pad VP4 and the sixth voltage pad VP6. A distance between the second power voltage supply line VSL and the side of the device substrate 100 at the outside of the pad area PAD can be smaller than a distance between the pad area PAD and the side of the device substrate 100. For example, the distance between the second power voltage supply line VSL and the side of the device substrate 100 at the outside of the pad area PAD can be smaller than a distance between the first voltage pad VP1 and the side of the device substrate 100. Thus, in the display apparatus according to the embodiment of the present disclosure, a current path between each voltage pad VSP and the second power voltage supply line VSL can have different lengths according to the location of the corresponding voltage pad VSP. For example, in the display apparatus according to the embodiment of the present disclosure, a current path between the second voltage pad VP2 and the second power voltage supply line VSL can be longer than a current path between the first voltage pad VP1 and the second power voltage supply line VSL, and a current path between the third voltage pad VP3 and the second power voltage supply line VSL can be longer than the current path between the second voltage pad VP2 and the second power voltage supply line VSL. Further, in the display apparatus according to the embodiment of the present disclosure, a current path between the fifth voltage pad VP5 and the second power voltage supply line VSL can be shorter than a current path between the sixth voltage pad VP6 and the second power voltage supply line VSL, a current path between the fourth voltage pad VP4 and the second power voltage supply line VSL can be shorter than the current path between the fifth voltage pad VP5 and the second power voltage supply line VSL, and the current path between the third voltage pad VP3 and the second power voltage supply line VSL can be shorter than the current path between the fourth voltage pad VP4 and the second power voltage supply line VSL.

A resistance of each voltage pad VSP can decrease as it moves away from an edge of the pad area PAD. For example, a resistance of the second voltage pad VP2 can be smaller than a resistance of the first voltage pad VP1, a resistance of the third voltage pad VP3 can be smaller than the resistance of the second voltage pad VP2, and a resistance of the fourth voltage pad VP4 can be smaller than the resistance of the third voltage pad VP3. Further, a resistance of the fifth voltage pad VP5 can be larger than a resistance of the sixth voltage pad VP6, and the resistance of the fourth voltage pad VP4 can be larger than the resistance of the fifth voltage pad VP5. Thus, in the display apparatus according to the embodiment of the present disclosure, the current flowing between the voltage pads VSP and the second power voltage supply line VSL can be distributed to the first voltage pad VP1, the second voltage pad VP2, the third voltage pad VP3, the fourth voltage pad VP4, the fifth voltage pad VP5 and the sixth voltage pad VP6. For example, in the display apparatus according to the embodiment of the present disclosure, the current flowing between the sixth voltage pad VP6 and the second power voltage supply line VSL can be larger than the current flowing between the first voltage pad VP1 and the second power voltage supply line VSL. Therefore, in the display apparatus according to the embodiment of the present disclosure, the current concentration due to the difference in the current path of the voltage pads VSP can be reduced by the difference in the resistance of the voltage pads VSP. For example, in the display apparatus according to the embodiment of the present disclosure, the heat generation due to the current concentration between the voltage pads VSP and the second power voltage supply line VSL can be reduced.

Each of the voltage pads VSP can have a same stacked structure. For example, each of the voltage pads can have a stacked structure of a lower pad electrode P1 and an upper pad electrode P2. The upper pad electrode P2 of each voltage pad VSP can be disposed on the lower pad electrode P1 of the corresponding voltage pad VSP. The upper pad electrode P2 of each voltage pad VSP can be electrically connected to the lower pad electrode P1 of the corresponding voltage pad VSP. For example, the upper pad electrode P2 of each voltage pad VSP can be in direct contact with the lower pad electrode P1 of the corresponding voltage pad VSP.

The lower pad electrode P1 and the upper pad electrode P2 of each voltage pad VSP can be formed by using a process of forming the driving circuit DC and the light-emitting device 300 of each pixel area PA. For example, the lower pad electrode P1 of each voltage pad VSP can include a same material as the second gate electrode 223 of each pixel area PA, and the upper pad electrode P2 of each voltage pad VSP can include a same material as the first electrode 310 of each pixel area PA. The lower pad electrode P1 of each voltage pad VSP can be disposed on a same layer as the second gate electrode 223 of each pixel area PA. For example, the lower pad electrode P1 of each voltage pad VSP can be disposed between the gate insulating layer 120 and the device passivation layer 130 of the pad area PAD. The upper pad electrode P2 of each voltage pad VSP can be disposed on a same layer as the first electrode 310 of each pixel area PA. For example, the upper pad electrode P2 of each voltage pad VSP can be disposed on the planarization layer 140 of the pad area PAD. The device passivation layer 130 and the planarization layer 140 of the pad area PAD can include pad contact holes partially exposing the lower pad electrode P1 of each voltage pad VSP. The upper pad electrode P2 of each voltage pad VSP can be in direct contact with the lower pad electrode P1 of the corresponding voltage pad VSP through one of the pad contact holes. The lower pad electrode P1 of each voltage pad VSP can be formed by a same process as the second gate electrode 223 of each pixel area PA, and the upper pad electrode P2 of each voltage pad VSP can be formed by a same process as the first electrode 310 of each pixel area PA. For example, the lower pad electrode P1 of each voltage pad VSP can be formed simultaneously with the second gate electrode 223 of each pixel area PA, and the upper pad electrode P2 of each voltage pad VSP can be formed simultaneously with the first electrode 310 of each pixel area PA.

The lower pad electrode P1 of each voltage pad VSP can be disposed on a same layer as the second power voltage supply line VSL. The second power voltage supply line VSL can be electrically connected to the lower pad electrode P1 of each voltage pad VSP. For example, the second power voltage supply line VSL can be in direct contact with the lower pad electrode P1 of each voltage pad VSP. The second power voltage supply line VSL can include a same material as the lower pad electrode P1 of each voltage pad VSP. For example, a boundary between the lower pad electrode P1 of each voltage pad VSP and the second power voltage supply line VSL cannot be recognized.

Each of the voltage pads VSP can have the same length. A horizontal width of each voltage pad VSP can be different. For example, a horizontal width W2 of the second voltage pad VP2 can be greater than a horizontal width W1 of the first voltage pad VP1, a horizontal width W3 of the third voltage pad VP3 can be greater than the horizontal width W2 of the second voltage pad VP2. The fifth voltage pad VP5 can have a horizontal width smaller than the sixth voltage pad VP6, the fourth voltage pad VP4 can have a horizontal width smaller than the fifth voltage pad VP5, and the third voltage pad VP3 can have a horizontal width smaller than the fourth voltage pad VP4. For example, in the display apparatus according to the embodiment of the present disclosure, a resistance of each voltage pad VSP can be adjusted by a horizontal width of the corresponding voltage pad VSP. Therefore, in the display apparatus according to the embodiment of the present disclosure, the decrease in the process efficiency due to a process of forming the voltage pads VSP having different resistances can be prevented.

The voltage pads VSP can be formed with a constant pitch. The voltage pads VSP can also be formed with a varied pitch. For example, a distance d2 between the second voltage pad VP2 and the third voltage pad VP3 can be smaller than a distance d1 between the first voltage pad VP1 and the second voltage pad VP2. A distance between the third voltage pad VP3 and the fourth voltage pad VP4 can be smaller than the distance d2 between the second voltage pad VP2 and the third voltage pad VP3, a distance between the fourth voltage pad VP4 and the fifth voltage pad VP5 can be smaller than the distance between the third voltage pad VP3 and the fourth voltage pad VP4, and a distance between the fifth voltage pad VP5 and the sixth voltage pad VP6 can be smaller than the distance between the fourth voltage pad VP4 and the fifth voltage pad VP5. The sum of the horizontal width W1 of the first voltage pad VP1 and the distance d1 between the first voltage pad VP1 and the second voltage pad VP2 can be the same as the sum of the horizontal width W2 of the second voltage pad VP2 and the distance between the second voltage pad VP2 and the third voltage pad VP3.

Accordingly, the display apparatus according to the embodiment of the present disclosure can include the pad area PAD disposed outside the active area AA, wherein the pad area PAD can include a plurality of voltage pads VSP electrically connected to the second power voltage supply line VSL that extends along an edge of the device substrate 100, wherein a resistance of each voltage pad VSP can decrease toward the center of the pad area PAD. Thus, in the display apparatus according to the embodiment of the present disclosure, the current flowing between the pad area PAD and the second power voltage supply line VSL can be distributed to the plurality of voltage pads VSP. Therefore, in the display apparatus according to the embodiment of the present disclosure, the heat generation due to the current concentration between the pad area PAD and the second power voltage supply line VSL can be reduced. For example, in the display apparatus according to the embodiment of the present disclosure, the deterioration of the light-emitting devices 300 due to heat can be prevented.

Further, in the display apparatus according to the embodiment of the present disclosure, a resistance of each voltage pad VSP can be adjusted by a horizontal width of the corresponding voltage pad VSP. Thus, in the display apparatus according to the embodiment of the present disclosure, the current flowing between the pad area PAD and the second power voltage supply line VSL can be distributed, without the decrease of the process efficiency. Therefore, in the display apparatus according to the embodiment of the present disclosure, the production energy can be reduced by process optimization.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor for initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrode 225, the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain region of the corresponding driving circuit DC. Thus, in the display apparatus according to another embodiment of the present disclosure, the degree of freedom in the configuration of each driving circuit DC and the type of each thin film transistor TR1 and TR2 can be improved.

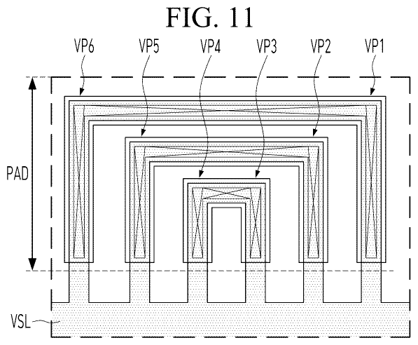

The display apparatus according to the embodiment of the present disclosure is described that the first drain electrode and the first source electrode of each pixel area PA can be disposed on a same layer as the first gate electrode of the corresponding pixel area PA, and the second drain electrode 225 and the second source electrode 227 of each pixel area PA can be disposed on a same layer as the second gate electrode 223 of the corresponding pixel area PA. However, in the display apparatus according to another embodiment of the present disclosure, the first thin film transistor TR1 and the second thin film transistor TR2 of each pixel area PA can have various structures. For example, in the display apparatus according to the embodiment of the present disclosure, the second drain electrode 225 and the second source electrode 227 of each pixel area PA can be disposed on a different layer from the second gate electrode 223 of the corresponding pixel area PA, as shown in FIG. 7.

An interlayer insulating layer 160 can be disposed between the gate insulating layer 120 and the device passivation layer 130 of the device substrate 100. The second drain electrode 225 and the second source electrode 227 of each pixel area PA can be insulated from the second gate electrode 223 of the corresponding pixel area PA by the interlayer insulating layer 160. For example, the interlayer insulating layer 160 can cover the second gate electrode 223 of each pixel area PA. The second drain electrode 225 and the second source electrode 227 of each pixel area PA can be disposed on the interlayer insulating layer 160. The interlayer insulating layer 160 can include an insulating material. For example, the interlayer insulating layer 160 can include an inorganic insulating material. Thus, in the display apparatus according to another embodiment of the present disclosure, the degree of freedom for the configuration of the second thin film transistor TR2 in each pixel area PA can be improved.

The display apparatus according to the embodiment of the present disclosure is described that the second power voltage supply line VSL can be in direct contact with the lower pad electrode P1 of each voltage pad VSP. However, in the display apparatus according to another embodiment of the present disclosure, each of the voltage pads VSP can be connected to the second power voltage supply line VSL in various ways. For example, in the display apparatus according to another embodiment of the present disclosure, connection electrodes CL can be disposed between the device substrate 100 and the buffer insulating layer 110 of the pad area PAD, each of the voltage pads VSP can be electrically connected to the second power voltage supply line VSL through one of the connection electrodes CL, as shown in FIGS. 8 and 9. The connection electrodes CL can include a conductive material. For example, the connection electrode CL can include a metal.

The connection electrodes CL can be disposed on a same layer as the light-blocking patterns in each pixel area PA. The connection electrodes CL can include a same material as the light-blocking patterns in each pixel area PA. The connection electrodes CL can be formed by a same process as the light-blocking patterns in each pixel area PA. For example, the connection electrodes CL can be formed simultaneously with the light-blocking patterns in each pixel area PA. Thus, in the display apparatus according to another embodiment of the present disclosure, the decrease in the process efficiency due to a process of forming the connection electrodes CL can be prevented.

The lower pad electrode P1 of each voltage pad VSP can be disposed on a same layer as the second power voltage supply line VSL. For example, the lower pad electrode P1 of each voltage pad VSP can be electrically connected to the corresponding connection electrode CL through at least one pad contact hole Ph. The pad contact hole Ph can penetrate the buffer insulating layer 110 and the gate insulating layer 120 of the pad area PAD. The number of the pad contact hole Ph electrically connecting the lower pad electrode P1 of each voltage pad VSP to the second power voltage supply line VSL can increase toward the center of the pad area PAD. For example, in the display apparatus according to another embodiment of the present disclosure, the number of the pad contact hole Ph connecting between the lower pad electrode P1 of the second voltage pad VP2 and the corresponding connection electrode CL can be greater than the number of the pad contact hole Ph connecting between the lower pad electrode P1 of the first voltage pad VP1 and the corresponding connection electrode CL, and the number of the pad contact hole Ph connecting between the lower pad electrode P1 of the third voltage pad VP3 and the corresponding connection electrode CL can be greater than the number of the pad contact hole Ph connecting between the lower pad electrode P1 of the second voltage pad VP2 and the corresponding connection electrode CL. Further, in the display apparatus according to another embodiment of the present disclosure, the number of the pad contact hole Ph connecting between the lower pad electrode P1 of the fourth voltage pad VP4 and the corresponding connection electrode CL can be greater than the number of the pad contact hole Ph connecting between the lower pad electrode P1 of the third voltage pad VP3 and the corresponding connection electrode CL, the number of the pad contact hole Ph connecting between the lower pad electrode P1 of the fifth voltage pad VP5 and the corresponding connection electrode CL can be greater than the number of the pad contact hole Ph connecting between the lower pad electrode P1 of the fourth voltage pad VP4 and the corresponding connection electrode CL, and the number of the pad contact hole Ph connecting between the lower pad electrode P1 of the sixth voltage pad VP6 and the corresponding connection electrode CL can be greater than the number of the pad contact hole Ph connecting between the lower pad electrode P1 of the fifth voltage pad VP5 and the corresponding connection electrode CL. Thus, in the display apparatus according to another embodiment of the present disclosure, an area of region for connection between each voltage pad VSP and the second power voltage supply line VSL can increase toward the center of the pad area PAD. For example, in the display apparatus according to another embodiment of the present disclosure, a resistance of each voltage pad VSP can be determined by the number of the pad contact hole Ph overlapping with the corresponding voltage pad VSP. Therefore, in the display apparatus according to another embodiment of the present disclosure, the degree of freedom for the configuration of each voltage pad VSP can be improve, without the decrease of the process efficiency.

In the display apparatus according to another embodiment of the present disclosure, each of the voltage pads VSP can include a first end Pe1 toward the second power voltage supply line VSL and a second end Pe2 opposite to the first end Pe1, and the pad contact hole Ph for connection between each voltage pad VSP and the second power voltage supply line VSL can be disposed close to the second end Pe2 of the corresponding voltage pad VSP. Thus, in the display apparatus according to another embodiment of the present disclosure, the current path between each voltage pad VSP and the second power voltage supply line VSL can be increased by the location of the pad contact hole Ph. For example, in the display apparatus according to another embodiment of the present disclosure, the deviation in the current path due to the different in the location of the voltage pads VSP can be reduced by the location of the pad contact hole Ph. Therefore, in the display apparatus according to another embodiment of the present disclosure, the current flowing between the pad area PAD and the second power voltage supply line VSL can be effectively distributed to the plurality of voltage pads VSP, without the decrease of the process efficiency.

In the display apparatus according to another embodiment of the present disclosure, the lower pad electrode P1 of each voltage pad VSP can have different sizes. For example, in the display apparatus according to another embodiment of the present disclosure, an area of the lower pad electrode P1 of each voltage pad VP1, VP2, VP3, VP4, VP5 and VP6 can decrease toward an edge of the pad area PAD, as shown in FIG. 10. The lower pad electrode P1 of the first voltage pad VP1 can have a smaller size than the lower pad electrode P1 of the second voltage pad VP2, the lower pad electrode P1 of the second voltage pad VP2 can have a smaller size than the lower pad electrode P1 of the third voltage pad VP3, and the lower pad electrode P1 of the third voltage pad VP3 can have a smaller size than the lower pad electrode P1 of the fourth voltage pad VP4. The lower pad electrode P1 of the sixth voltage pad VP6 can have a larger size than the lower pad electrode P1 of the fifth voltage pad VP5, and lower pad electrode P1 of the fifth voltage pad VP5 can have a larger size than the lower pad electrode P1 of the fourth voltage pad VP4. Thus, in the display apparatus according to another embodiment of the present disclosure, a resistance between the upper pad electrode P2 of each voltage pad VP1, VP2, VP3, VP4, VP5 and VP6 and the corresponding connection electrode CL can decrease toward the center of the pad area PAD. Therefore, in the display apparatus according to another embodiment of the present disclosure, the heat generation due to the current concentration between the pad area PAD and the second power voltage supply line VSL can be effectively reduced, without the decrease of the process efficiency.

The display apparatus according to the embodiment of the present disclosure is described that a resistance of the voltage pads VSP can decrease toward the center of the pad area PAD. However, in the display apparatus according to another embodiment of the present disclosure, various structures can be used to reduce the heat generation due to the current concentration between the pad area PAD and the second power voltage supply line VSL. For example, in the display apparatus according to another embodiment of the present disclosure, the sixth voltage pad VP6 can be connected to the first voltage pad VP1, the fifth voltage pad VP5 can be connected to the second voltage pad VP2, and the fourth voltage pad VP4 can be connected to the third voltage pad VP3, as shown in FIG. 11. Thus, in the display apparatus according to another embodiment of the present disclosure, the third voltage pad VP3 and the fourth voltage pad VP4 can have a relatively small resistance, and the first voltage pad VP1 and the sixth voltage pad VP6 can have a relatively large resistance. For example, in the display apparatus according to another embodiment of the present disclosure, the current flowing between the pad area PAD and the second power voltage supply line VSL can be distributed around the third voltage pad VP3 and the fourth voltage pad VP4. Therefore, in the display apparatus according to another embodiment of the present disclosure, the degree of freedom for the arrangement and the shape of the voltage pads VP1, VP2, VP3, VP4, VP5 and VP6 in the pad area PAD can be improved.

As a result, the display apparatus according to the embodiments of the present disclosure can comprise the pad area and the power voltage supply line that are disposed outside the active area, wherein the power voltage supply line can extend along an edge of the device substrate, wherein the pad area can include the voltage pads electrically connected to the power voltage supply line, and wherein each of the voltage pads can have a different resistance from adjacent voltage pad.

Thus, in the display apparatus according to the embodiments of the present disclosure, the current flowing between the power voltage supply line and the voltage pads can be distributed. For example, in the display apparatus according to the embodiments of the present disclosure, heat generation due to the current concentration can be prevented or minimized. Accordingly, in the display apparatus according to the embodiments of the present disclosure, heat generation due to the difference in the current path in the pad area can be prevented or minimized, and the deterioration of the light-emitting devices can be reduced or prevented. Further, in the display apparatus according to the embodiments of the present disclosure, production energy can be reduced by process optimization.

The present disclosure being thus described, it will be obvious that the same may be varied in many ways. Such variations are not to be regarded as a departure from the spirit and scope of the present disclosure, and all such modifications as would be obvious to one skilled in the art are intended to be included within the scope of the following claims.

What is claimed is:

1. A display apparatus comprising:
a device substrate including a bezel area disposed outside an active area;
a pad area disposed in the bezel area, the pad area including a first voltage pad and a second voltage pad, which are disposed side by side along an edge of the active area; and
a power voltage supply line extending along an edge of the device substrate, the power voltage supply line electrically connected to the first voltage pad and the second voltage pad,
wherein the first voltage pad is disposed between the second voltage pad and a side of the device substrate, and
wherein the second voltage pad has a different resistance from the first voltage pad.

2. The display apparatus according to the claim 1, wherein a distance between the power voltage supply line and the side of the device substrate in the outside of the pad area is smaller than a distance between the first voltage pad and the side of the device substrate in the outside of the pad area.

3. The display apparatus according to claim 1, wherein the second voltage pad has a stacked structure that is same as the first voltage pad.

4. The display apparatus according to claim 3, wherein each of the first voltage pad and the second voltage pad includes a first pad electrode and a second pad electrode disposed on the first pad electrode, and
wherein the first pad electrode includes a same material as the power voltage supply line.

5. The display apparatus according to claim 1, wherein a horizontal width of the second voltage pad is different from a horizontal width of the first voltage pad.

6. The display apparatus according to claim 5, wherein the second voltage pad has a same length as the first voltage pad.

7. The display apparatus according to claim 5, wherein the pad area includes a third voltage pad electrically connected to the power voltage supply line,
wherein the second voltage pad is disposed between the first voltage pad and the third voltage pad,
wherein the second voltage pad has a resistance between the first voltage pad and the third voltage pad, and
wherein the horizontal width of the second voltage pad falls between the horizontal width of the first voltage pad and a horizontal width of the third voltage pad.

8. The display apparatus according to claim 7, wherein a distance between the second voltage pad and the third voltage pad is different from a distance between the first voltage pad and the second voltage pad.

9. The display apparatus according to claim 1, wherein a signal applied to the power voltage supply line through the second voltage pad is the same as a signal applied to the power voltage supply line through the first voltage pad.

10. The display apparatus according to claim 9, wherein the signal applied to the power voltage supply line through the first voltage pad and the second voltage pad is a negative power voltage.

11. The display apparatus according to claim 1, wherein the pad area includes a third voltage pad, a fourth voltage pad, a fifth voltage pad, and a sixth voltage pad successively disposed side by side along the edge of the active area and next to the second voltage pad, and the sixth voltage pad is connected to the first voltage pad, the fifth voltage pad is connected to the second voltage pad, and the fourth voltage pad is connected to the third voltage pad.

12. A display apparatus comprising:
a device substrate including a bezel area disposed outside an active area;
a pad area disposed in the bezel area, the pad area including a plurality of voltage pads disposed side by side to each other; and
a power voltage supply line extending along an edge of the device substrate, the power voltage supply line electrically connected to the plurality of voltage pads,
wherein an area of a region for the connection between each voltage pad and the power voltage supply line increases toward a center of the pad area.

13. The display apparatus according to claim 12, wherein a plane of each voltage pad has a same shape as a plane of an adjacent voltage pad.

14. The display apparatus according to claim 12, wherein each of the plurality of voltage pads includes a lower pad electrode and an upper pad electrode disposed on the lower pad electrode,
wherein the power voltage supply line is electrically connected to the lower pad electrode of each voltage pad through at least one pad contact hole, and
wherein a number of the at least one pad contact hole connecting between the lower pad electrode of each voltage pad and the power voltage supply line increases toward the center of the pad area.

15. The display apparatus according to claim 14, wherein each of the plurality of voltage pads includes a first end toward the power voltage supply line and a second end opposite to the first end, and
wherein the at least one pad contact hole connecting between the lower pad electrode of each voltage pad and the power voltage supply line is disposed close to the second end of the corresponding voltage pad.

16. The display apparatus according to claim 14, further comprising connection electrodes disposed between the power voltage supply line and each voltage pad,
wherein each of the plurality of voltage pads is electrically connected to the power voltage supply line through one of the connection electrodes.

17. The display apparatus according to claim 16, wherein the connection electrodes are disposed on a different layer than the power voltage supply line.

18. The display apparatus according to claim 16, further comprising:
a driving circuit disposed on a pixel area of the active area, the driving circuit including at least one thin film transistor;
a light-emitting device disposed on the pixel area of the active area, the light-emitting device electrically connected to the driving circuit; and
a light-blocking pattern disposed on the pixel area of the active area, the light-blocking pattern disposed between the device substrate and a semiconductor pattern of the at least one thin film transistor,
wherein the connection electrodes are disposed on a same layer as the light-blocking pattern.

19. The display apparatus according to claim 12, wherein each of the plurality of voltage pads includes a lower pad electrode and an upper pad electrode disposed on the lower pad electrode, and
wherein an area of the lower pad electrode of each voltage pad decreases toward an edge of the pad area.
